(19) United States
(12) Patent Application Publication
(10) Pub. No.: US 2005/0098865 A1
(43) Pub. Date: May 12, 2005

(54) Image sensor package

(76) Inventors: Jackson Hsieh, Hsinchu Hsien (TW); Jichen Wu, Hsinchu Hsien (TW); Worrell Tsai, Hsinchu Hsien (TW); Abnet Chen, Hsinchu Hsien (TW)

Correspondence Address: PRO-TECHTOR INTERNATIONAL, 20775 Norada Court, Saratoga, CA, 95070-3018, US

(21) Appl. No.: 10/705,377

(22) Filed: Nov. 10, 2003

(51) Int. Cl. H01L 23/02; H01L 23/48

(52) U.S. Cl. 257/678; 257/697; 257/704; 257/787

(57) ABSTRACT

An image sensor package includes plural lower metal sheets, plural upper metal sheets stacked on the lower metal sheets, and an encapsulant for encapsulating the lower and upper metal sheets. The lower metal formed with a first hole, the upper metal sheets formed a second hole penetrated from the upper surface to the lower surface. Wherein the encapsulant filled into the second hole and first hole to tighten the upper metal sheets and the lower metal sheets. A photosensitive chip arranged within the chamber, plural wires for electrically connecting the chip to the upper surfaces of the lower metal sheets, and a transparent layer arranged on the frame layer to cover the chip.

### BACKGROUND OF THE INVENTION

1. Field of the Invention

The invention relates to an image sensor package, and more particularly to an image sensor with increased product reliability and facilitated manufacturing processes.

2. Description of the Related Art

Referring to FIG. 1, which is a cross-sectional view showing an image sensor package. The image sensor includes a plurality of lower metal sheets 10 arranged in an array, each of the lower metal sheets 10 having an upper surface 26 and a lower surface 28. A plurality of upper metal sheets 12 arranged in an array, each of the upper metal sheets 12 having an upper surface 38 and a lower surface 40, the lower surfaces 40 of the upper metal sheets 12 being stacked on the upper surfaces 26 of the lower metal sheets 10. An encapsulant 14 is for encapsulating the lower metal sheets 10 and the upper metal sheets 12. Wherein the upper surfaces 38 of the upper metal sheets 12 are exposed from the encapsulant 14. The lower surfaces 28 of the lower metal sheets 10 are exposed from the encapsulant 14 and electrically connected to the printed circuit board, and the encapsulant 14 is formed with a frame layer 16 around the upper surfaces 38 of the upper metal sheets 12 to define a chamber 42 together with the upper metal sheets 12. A photosensitive chip 18 arranged within the chamber. A plurality of wires 20 are for electrically connecting the photosensitive chip 18 to the upper surfaces 38 of the upper metal sheets 12. A transparent layer 22 arranged on the frame layer 16 of the encapsulant 14 to cover the photosensitive chip 18.

The above-mentioned the patent has some advantages, but it has following drawbacks.

1. Since the wires 20 are electrically connected the chip 18 to the upper surface 38 of the upper metal sheets 12 for transmitting signals from the chip 18 to the lower metal sheets 12. Thus, the upper metals 12 and the lower metal sheets 10 much be tight stacked.

### SUMMARY OF THE INVENTION

An object of the invention is to provide an image sensor package with improved package reliability.

Still another object of the invention is to provide an image sensor package, wherein the wire bonding process may be easily performed and the product yield may be increased.

To achieve the above-mentioned objects, the invention includes plural lower metal sheets, plural upper metal sheets stacked on the lower metal sheets, and an encapsulant for encapsulating the lower and upper metal sheets. The lower metal formed with a first hole, the upper metal sheets formed a second hole penetrated from the upper surface to the lower surface. Wherein the encapsulant filled into the second hole and first hole to tighten the upper metal sheets and the lower metal sheets. A photosensitive chip arranged within the chamber, plural wires for electrically connecting the chip to the upper surfaces of the lower metal sheets, and a transparent layer arranged on the frame layer to cover the chip.

### BRIEF DESCRIPTION OF THE DRAWINGS

FIG. 1 is a cross-sectional view showing an image sensor package.

FIG. 2 is a cross-sectional view showing an image sensor package of the present invention.

FIG. 3 is a first schematic view showing an image sensor package of the invention.

FIG. 4 is a second schematic view showing an image sensor package of the invention.

FIG. 5 is a third schematic view showing an image sensor package of the invention.

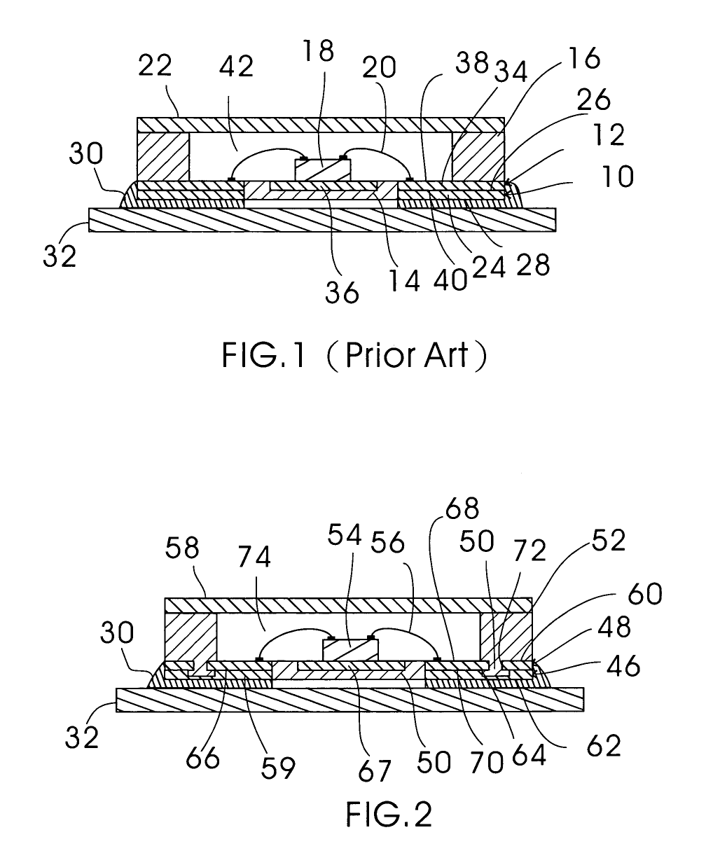

### DETAILED DESCRIPTION OF THE INVENTION

Referring to FIG. 2, an image sensor package of the invention includes a plurality of lower metal sheets 46 arranged in an array, a plurality of upper metal sheets 48 arranged in an array, an encapsulant 50, a frame layer 52, a photosensitive chip 54, a plurality of wires 56, and a transparent layer 58.

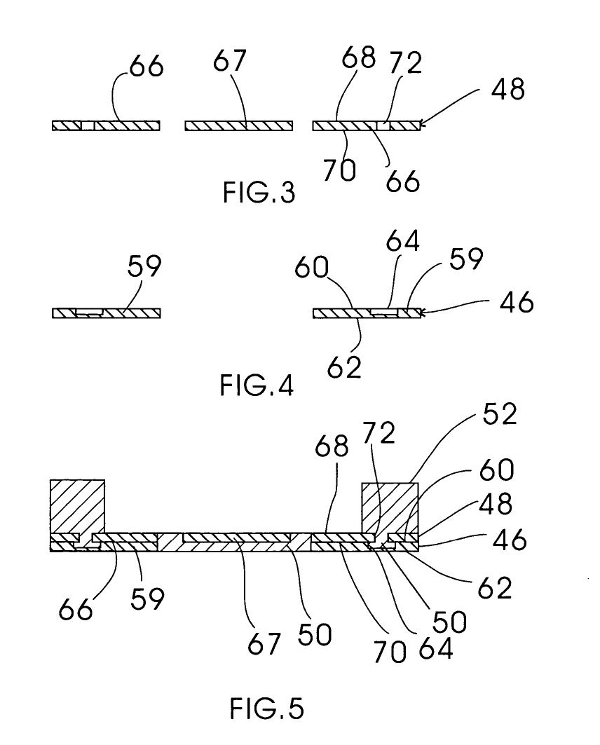

Please referring to FIG. 3 and FIG. 4, Each lower metal sheet 46 has an upper surface 60 and a lower surface 62, and formed with a first hole 64, which is a cavity.

Each of the upper metal sheet 48 has an upper surface 68 and a lower surface 70, and formed with a second hole 72 penetrated from the upper surface 68 to the lower surface 70. The lower surfaces 70 of the upper metal sheets 48 are stacked on the upper surfaces 60 of the lower metal sheets 46, then the second hole 72 corresponding with the first hole 64.

The encapsulant 54 is encapsulated the lower metal sheets 46 and the upper metal sheets 48 via integrated mold, and filled into the first hole 64 and the second hole 72 to tighten the lower metal sheets 46 and upper metal sheets 48. Wherein the upper surfaces 60 of the lower metal sheets 46 are exposed from the encapsulant 54. The lower surfaces 62 of the lower metal sheets 46 are exposed from the encapsulant 54 and electrically connected to the printed circuit board 32 via solder 30. The encapsulant 54 is formed with a frame layer 52 around the upper surfaces 68 of the upper metal sheets 48 to define a chamber 74 together with the upper metal sheets 48.

The photosensitive chip 54 is arranged on the middle board 67 and located within the chamber 74.

The plurality of wires 56 are electrically connected the photosensitive chip 54 to the upper surfaces 60 of the upper metal sheets 46 so as to transfer signals from the photosensitive chip 54 to the lower metal sheets 46.

The transparent layer 58 is a piece of transparent glass arranged on the frame layer 52 of the encapsulant 50 to cover the photosensitive chip 54. Thus, the photosensitive chip 54 may receive optical signals passing through the transparent layer 58.

The invention has the following advantages.
1. Since the combination of the upper and lower metal sheets 48 and 46 is thicker, the solder 30 may climb to the upper metal sheets 48 from the lower metal sheets 46 during the SMT process for mounting the image sensor to the printed circuit board 32. Therefore, the package body can be mounted to the printed circuit board 32 with great stability.
2. Since the encapsulant 54 is filled into the first hole 64 and first hole 72, so as to the upper metal sheets 48 and lower metal sheets 46 may package tight.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

1. An image sensor package to be electrically connected to a printed circuit board, the image sensor comprising:
a plurality of lower metal sheets arranged in an array, each of the low r metal sheets having an upper surface and a lower surface, and a first hole;
a plurality of upper metal sheets arranged in an array, each of the upper metal sheets having an upper surface and a lower surface, and a second hole penetrated from the upper surface to the lower surface, and the second hole being corresponded with the first hole of the lower metal sheets, the lower surface of the upper metal sheets being stacked on the lower metal;
an encapsulant for encapsulating the lower metal sheets and the upper metal sheets, and the encapsulant filled into the first hole and second hole to tighten the upper metal sheets and the lower metal sheets, wherein the upper surfaces of the lower metal sheets are exposed from the encapsulant, the lower surfaces of the lower metal sheets are exposed from the encapsulant and electrically connected to the printed circuit board, and the encapsulant is formed with a frame layer around the upper surfaces of the upper metal sheets to define a chamber together with the upper metal sheets;
a photosensitive chip being arranged within the chamber;
a plurality of wires for electrically connecting the photosensitive chip to the upper surfaces of the lower metal sheets;
a transparent layer arranged on the frame layer of the encapsulant to cover the photosensitive chip.

2. The image sensor package according to claim 1, wherein the encapsulant is made of industrial plastic material, and the encapsulant and the frame layer are integrally formed.

3. The image sensor package according to claim 1, wherein the transparent layer is a piece of transparent glass.

4. The image sensor package according to claim 1, wherein the first hole of the lower metal is a cavity.
